(19) United States
(12) Patent Application Publication
(10) Pub. No.: US 2016/0147125 A1
(43) Pub. Date: May 26, 2016

(54) ELECTRONIC DEVICES WTH TRANSPARENT CONDUCTING ELECTRODES, AND METHODS OF MANUFACTURE THEREOF

(71) Applicant: Freescale Semiconductor, Inc., Austin, TX (US)

(72) Inventor: NIRMAL DAVID THEODORE, MESA, TX (US)

(21) Appl. No.: 14/551,947

(22) Filed: Nov. 24, 2014

(51) Int. Cl. G02F 1/155; H01L 33/42; H01L 31/0224; H01L 33/38; H01L 31/18; C23C 14/06; G02F 1/1335; C23C 14/34; C23C 14/08; C23C 14/12; C23C 14/18; C23C 14/10; H01L 33/00; G02F 1/1343

(52) U.S. Cl. CPC G02F 1/155; H01L 33/0041; H01L 33/42; H01L 31/022491; H01L 33/38; H01L 31/1884; G02F 1/13439; G02F 1/133528; C23C 14/34; C23C 14/081; C23C 14/082; C23C 14/083; C23C 14/085; C23C 14/086; C23C 14/12; C23C 14/185; C23C 14/10; C23C 14/0676; C23C 14/067; C23C 14/0641; C23C 14/0623; C23C 14/0611; C23C 14/0605; C23C 14/0635; C23C 14/06; H01L 2933/0016

(57) ABSTRACT

An embodiment of a transparent conducting electrode includes a first non-conductive layer formed from a first non-conductive material, a conductive layer, and a second non-conductive layer formed from a second non-conductive material that is different from the first non-conductive material. One or more of the transparent conducting electrodes may be incorporated into electronic devices such as solar cells, light emitting diodes, electrochromic devices, liquid crystal displays, and other devices.

### TECHNICAL FIELD

Embodiments of the subject matter described herein relate generally to electronic devices with transparent conducting electrodes, and methods of their manufacture.

### BACKGROUND

Various types of electronic devices include transparent conducting electrodes. One of the most commonly used transparent conducting electrode materials is tin-doped indium oxide (ITO). ITO is suitable for use in transparent electrodes due to its low resistivity and its good transmittance (e.g., up to 80% or higher in the visible part of the spectrum), as well as its suitability for being deposited as a thin film. However, indium is relatively rare and expensive, and ITO films are brittle and susceptible to cracking. Further, fabricating a transparent electrode that includes indium presents some challenges. For example, after deposition, ITO requires a high temperature anneal (e.g., at about 250 degrees Celsius) to reduce its electrical resistivity and to increase its optical transmittance. In addition, indium can be toxic to humans. Therefore, special manufacturing and safety processes should be employed in fabricating devices that include indium. With the ever-increasing range of potential applications for transparent conducting electrodes, more available, less expensive, and safer transparent electrode materials and structures are desired.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a cross-sectional, side view of a transparent conducting electrode, in accordance with an example embodiment;

FIG. 2 is a flowchart of a method of manufacturing an electronic device with one or more transparent conducting electrodes, in accordance with an example embodiment;

FIG. 3 is a cross-sectional, side view of a solar cell, in accordance with an example embodiment;

FIG. 4 is a cross-sectional, side view of a light emitting diode, in accordance with an example embodiment;

FIG. 5 is a cross-sectional, side view of a portion of an electrochromic device, in accordance with an embodiment; and

FIG. 6 is a cross-sectional, side view of a portion of a liquid crystal display device, in accordance with an example embodiment.

### DETAILED DESCRIPTION

Embodiments of the inventive subject matter include transparent conducting electrodes, electronic devices that include transparent conducting electrodes, and methods of fabricating transparent conducting electrodes. Essentially, an embodiment of a transparent conducting electrode includes a first non-conductive layer formed from a first non-conductive material, a conductive layer on the first non-conductive layer and formed from an electrically conductive material, and a second non-conductive layer on the conductive layer and formed from a second non-conductive material that is different from the first non-conductive material. Transparent conducting electrodes according to such an embodiment may be incorporated into a wide variety of devices, including but not limited to solar cells, light emitting diodes, light emitting transistors, infrared sensors, ultraviolet sensors, electrochromic devices, tough screens, and liquid crystal displays.

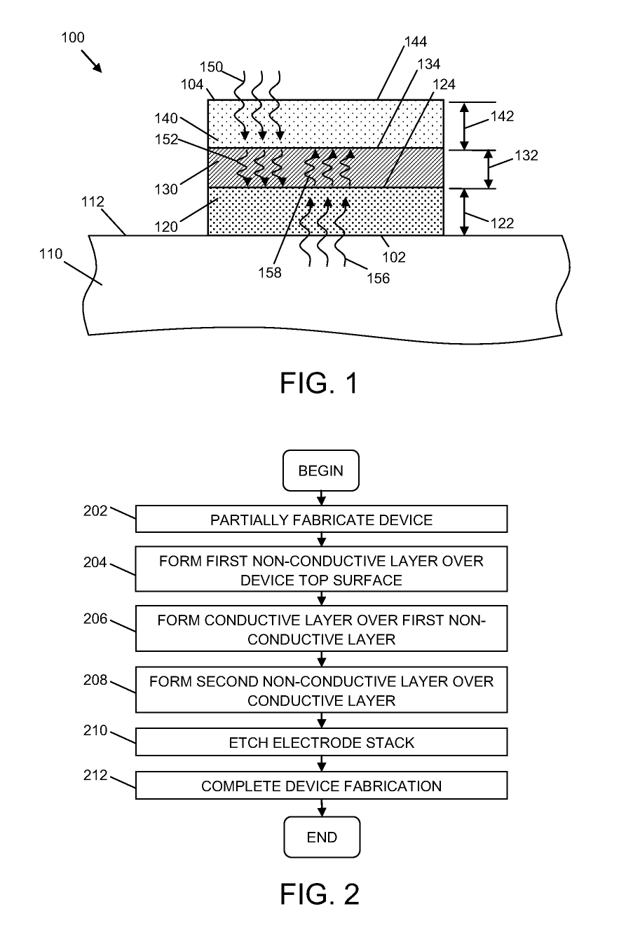

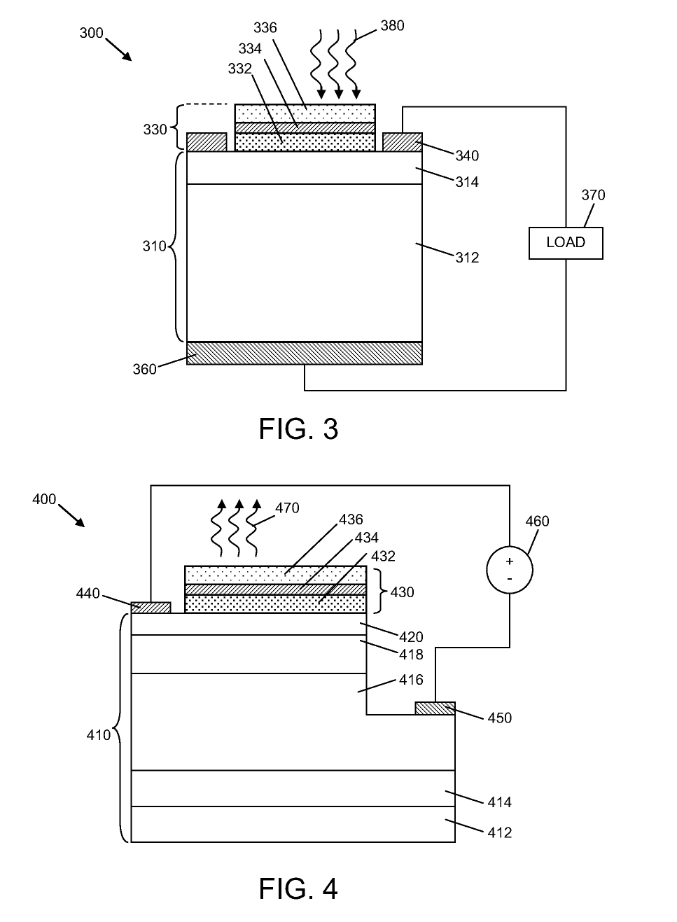

FIG. 1 is a cross-sectional, side view of a transparent conducting electrode 100, in accordance with an example embodiment. The transparent conducting electrode 100 is fabricated on a substrate 110, which has a configuration that depends on the type of device in which the transparent conducting electrode 100 is incorporated. Various different types of substrates 110 and devices will be described later in conjunction with FIGS. 3-6. In any event, the transparent conducting electrode 100 is fabricated on or over a surface 112 of the device substrate 110. The device substrate 110 can be formed from any of a variety of materials and their combinations, including semiconductor materials (e.g., silicon, gallium nitride, gallium arsenide, and so on), glass, plastic (e.g., polyethylene naphthalate), and so on.

The transparent conducting electrode 100 has a substrate-facing side 102 and an external side 104. When incorporated into some types of devices (e.g., solar cells), light 150 incident upon the external side 104 passes through the transparent conducting electrode 100 toward the substrate 110. When incorporated into other types of devices (e.g., light emitting diodes), light 156 incident upon the substrate facing side 102 passes through the transparent conducting electrode 100 toward the external side 104. As used herein, “incident light” refers to electromagnetic radiation in any of various wavelength ranges, including visible light (e.g., in a range of 380 to 760 nanometers (nm)), infrared (e.g., in a range of 750 nm to 1 millimeter (mm)), ultraviolet (i.e., in a range of 315 nm to 390 nm). Those of skill in the art would understand, based on the description herein, that the various embodiments may be implemented in devices configured to absorb or produce radiation in any of these ranges, or in other ranges as well.

According to an embodiment, the transparent conducting electrode 100 is formed from a plurality of relatively thin heterolayers, including a first non-conductive layer 120 formed on or over the surface 112 of the substrate 110, a conductive layer 130 formed on the first non conductive layer 120, and a second non-conductive layer 140 formed on the conductive layer 130. As used herein, “non-conductive” refers to a material or layer that has a conductivity of less than 1×10⁵ Siemens/meter (S/m), whereas “conductive” refers to a material or layer that has a conductivity of greater than 1×10⁵ S/m. Each of the layers 120, 130, 140 is “transparent,” according to an embodiment, meaning that the material and physical properties of each of the layers 120, 130, 140 are selected so that the layers 120, 130, 140 have transmittance of greater than 70% in an electromagnetic energy band of interest. For example, the first non-conductive layer 120 may have a thickness 122 in a range of about 20 nm to about 30 nm, the conductive layer 130 may have a thickness 132 in a range of about 8 nm to about 10 nm, and the second non-conductive layer 140 may have a thickness 142 in a range of about 20 nm to about 30 nm. In other embodiments, layers 120, 130, 140 may be thinner or thicker than the above-given ranges. The thicknesses 122, 132, 142 of layers 120, 130, 140 are selected to allow energy (or light) within a desired electromagnetic radiation band to pass relatively easily through the electrode 100. For example, the thicknesses 122, 132, 142 may be approximately equal to lambda/4, in some embodiments, although at least some of the thicknesses 122, 132, 142 may be significantly larger or smaller than lambda/4, as well.

The first and second non-conductive layers 120, 140 are formed from different materials, which enables the transparent conducting electrode 100 to be optimally configured for different purposes, according to various embodiments. More specifically, the first and second non-conductive layers 120, 140 may be selected to have different reflectivities for light propagation in one direction through the electrode 100 (e.g., from an exterior of the electrode toward the substrate 110 (i.e., top to bottom in FIG. 1)) than for light propagation in the other direction (e.g., from the substrate 110 toward an exterior of the electrode (i.e., bottom to top in FIG. 1)). This is achieved by selecting the materials for the non-conductive layers 120, 140 to have different refractive indices. According to an embodiment, the first non-conductive layer 120 has a first refractive index, and the second non-conductive layer 140 has a second and different refractive index from the first refractive index. Accordingly, because both non-conductive layers 120, 140 interface with the conductive layer 130, the reflectivity of incident light 150 (from the direction of the exterior of the device) at the interface 134 between the second non-conductive layer 140 and the conductive layer 130 has a first value, and the reflectivity of incident light 156 (from the direction of substrate 110) at the interface 134 between the first non-conductive layer 120 and the conductive layer 130 has a second value that is different from the first value. Similarly, the reflectivity of incident light 152 (from the direction of the exterior of the device) at the interface 124 between the conductive layer 130 and the first non-conductive layer 120 has a third value, and the reflectivity of incident light 158 (from the direction of substrate 110) at the interface 134 between the conductive layer 130 and the second non-conductive layer 140 has a fourth value that is different from the third value.

According to a specific embodiment, the reflectivity of incident light 150 in the top-down direction at the interface 134 between the second non-conductive layer 140 and the conductive layer 130 is relatively low, when compared with the reflectivity of incident light 156 in the bottom-up direction at the interface 124 between the first non-conductive layer 120 and the conductive layer 130. In other words, the material for the second non-conductive layer 140 is selected so that the reflectivity at interface 134 is relatively low, thus the second non-conductive layer 140 may function as an anti-reflection coating (ARC), which increases (and possibly maximizes) energy coming into the device by minimizing the reflectance of the conductive layer 130. According to an embodiment, the material of the second non-conductive layer 140 has a refractive index that matches, to the extent possible or practical, the extinction coefficient of the material of the conductive layer 130 in a desired spectral range. Selecting a material for the second non-conductive layer 140 that has a relatively higher refractive index may allow higher infrared reflectance, which may be desired for some applications. Conversely, selecting a material for the second non-conductive layer 140 that has a relatively lower refractive index may be more suitable for applications in which broader band transparency is desired.

Conversely, the material for the first non-conductive layer 120 is selected so that the reflectivity at interface 124 is relatively high, thus increasing (and possibly maximizing) energy retention within the device. Accordingly, greater amounts of incident light 150 (or energy) may be able to enter the substrate 110, whereas lesser amounts of incident light 156 (or energy) may be able to exit the substrate 110. In other words, based on the selection of materials for the first and second non-conductive layers 120, 140, the transparent conducting electrode 100 may be configured to have high energy absorption and retention within the substrate 110, in an embodiment. Such an embodiment may be particularly beneficial, for example, when implemented in a solar cell (e.g., solar cell 300, FIG. 3), and in particular, a combination optical-thermal solar cell (i.e., a solar cell in which energy conversion includes a photonic component and a thermal component). Maximizing energy retention within such a solar cell through careful selection of the materials of the first and second non-conductive layers 120, 140 may significantly increase the efficiency of the solar cell.

According to other embodiments, the material of the second non-conductive layer 140 may be chosen for optimized resistance to environmental exposure (e.g., wear resistance, scratch resistance, corrosion resistance, moisture resistance, oxidation resistance, sodium resistance, and/or other chemical resistance). Conversely, the material of the first non-conductive layer 120 may be independently chosen for maximized transmittance independent of its resistance to environmental exposure. For example, a relatively high transmittance (but low environmentally resistant) material may be selected for the first non-conductive layer 120, whereas a relatively high environmentally resistant material may be selected for the second non-conductive layer 140.

According to yet another embodiment, the material for the first non-conductive layer 120 may be chosen to ensure a relatively low (and possibly minimum) interfacial energy between the first non-conductive layer 120 and the conductive layer 130. The choice of material for the first non-conductive layer 120 determines the nucleation of the conductive layer 130 that is deposited on the first non-conductive layer 120. Thus, selecting a material with low interfacial energy may ensure continuous layer formation and minimize islanding of the conductive layer 130 on the first non-conductive layer 120. This, in turn, may enable a reduction of the thickness of the metal layer for good transmittance with adequate electrical conduction, thus enhancing overall transmittance of the transparent conducting electrode 100.

Other characteristics and factors also or alternatively may be used to select the materials for the first and second non-conductive layers 120, 140. For example, other selection characteristics include cost, hardness, mechanical strength, thermal stability, thermal shock resistance, thermal conductivity, adhesion to glass or other substrates, bandwidth of transmittance for a particular range of wavelengths, dielectric constant, ultraviolet absorption capability, semiconductor properties, superconductor properties, catalytic properties, thermo-chromic properties, photo-chromic properties, gas-chromic properties, photo-catalytic properties, photo-luminescent properties, magneto-resistive properties, piezoelectric properties, emission wavelengths, toxicity, environmental impacts, deposition temperatures, and other manufacturing factors.

The material of the conductive layer 130 may be selected from any of a variety of suitably conductive materials, including silver (Ag), copper (Cu), gold (Au), aluminum (Al), graphene, a conducting polymer material, a conducting organic material, carbon nanotube sheets (with or without doping), and other suitable conductive materials.

As discussed previously, the materials of the first and second non-conductive layers 120, 140 are different from each other. Desirably, the materials of the first and second non-conductive layers 120, 140 are selected and configured to have transmittance of greater than 70% in an electromagnetic energy band of interest. In some cases, the materials of either or both of the first or second non-conductive layers 120, 140 may have a transmittance of less than 70%.

According to some embodiments, the materials for the first and second non-conductive layers 120, 140 are selected from different transparent conductive oxides (TCOs), which have greater than 70% transmittance of incident light or energy (in a desired band) and conductivities up to 10³ S/cm. The first and second non-conductive layers 120, 140 may be fabricated with polycrystalline or amorphous microstructures, in various embodiments. More specifically, the first non-conductive layer 120 includes a first oxide, while the second non-conductive layer 140 includes a different, second oxide, in an embodiment. For example, the materials for the first and second non-conductive layers 120, 140 may be selected from aluminum oxide (Al₂O₃), barium oxide/tellurium oxide (BaO—TeO₂), indium tin oxide (InSnO), cerium oxide (CeO), nickel oxide (NiO), niobium oxide (NbO) (including niobium dioxide, and niobium pentoxide), silicon dioxide (SiO₂), tin oxide (SnO), tantalum oxide (Ta₂O₅), tungsten oxide (WO), zinc oxide (ZnO), chromium oxide (CrO), manganese oxide (MnO₂), titanium oxide (TiO₂), zirconium oxide (ZrO), boron bismuth oxide (BBiO), indium tin oxide (ITO), fluorine doped tin oxide (FTO), aluminum doped zinc oxide (AZO), indium-doped cadmium-oxide, other doped metal oxides, and other suitable transparent conductive oxides.

For example, an embodiment of a transparent conducting electrode that includes different TCO materials for the first and second non-conductive layers 120, 140 may include a first non-conductive layer 120 formed from ZnO, a conductive layer 130 formed from Ag, and a second non-conductive layer 140 formed from Al₂O₃. Another embodiment of a transparent conducting electrode that includes different TCO materials for the first and second non-conductive layers 120, 140 may include a first non-conductive layer 120 formed from CeO, a conductive layer 130 formed from Cu, and a second non-conductive layer 140 formed from Al₂O₃. Various other combinations of TCO materials and conductive materials for the layers 120, 130, 140 of a transparent conducting electrode alternatively may be used to achieve the desired characteristics of the transparent conducting electrode for the intended application.

According to other embodiments, the materials for the first and second non-conductive layers 120, 140 are selected from different non-oxides (e.g., dielectrics). More specifically, the first non-conductive layer 120 is a first non-oxide, while the second non-conductive layer 140 is a different, second non-oxide, in an embodiment. For example, the materials for the first and second non-conductive layers 120, 140 may be selected from various nitrides (e.g., including examples listed below), metal-nitrides, semiconductor-nitrides, oxynitrides (e.g., aluminum oxynitride (AlON) and other oxynitrides), metal-oxynitrides, semiconductor-oxynitrides, borides, hydrides, fluorides (e.g., magnesium fluoride (MgF₂), lithium fluoride (LiF), and other fluorides), carbides (e.g., silicon carbide (SiC) and other carbides), nanocarbon (e.g., carbon nanotube sheets, grapheme sheets, and other nanocarbons), selenides (e.g., germanium arseno-selenide (GeAsSe), germanium selenide (GeSe), arsenic selenide (AsSe), and other selenides), sulfides (e.g., arsenic sulfide (AsS), zinc sulfide (ZnS), and other sulfides), silicates, aluminates, diamond, diamondoid, polymers, organics, and other suitable non-oxides. For example, particularly well suited nitrides include aluminum nitride (AlN), boron nitride (BN), carbon nitride (CN), iron boron nitride (FeBN), tin nitride (SnN), and silicon nitride (Si₃N₄). Other nitrides that may be selected include titanium nitride (TiN), titanium aluminum nitride (TiAlN), chromium nitride (CrN), zinc nitride (ZnN), and copper nitride (CuN).

For example, an embodiment of a transparent conducting electrode that includes different non-oxide materials for the first and second non-conductive layers 120, 140 may include a first non-conductive layer 120 formed from MgF, a conductive layer 130 formed from Ag, and a second non-conductive layer 140 formed from AlN. Another embodiment of a transparent conducting electrode that includes different non-oxide materials for the first and second non-conductive layers 120, 140 may include a first non-conductive layer 120 formed from LiF, a conductive layer 130 formed from Cu, and a second non-conductive layer 140 formed from BN. Various other combinations of non-oxide materials and conductive materials for the layers 120, 130, 140 of a transparent conducting electrode alternatively may be used to achieve the desired characteristics of the transparent conducting electrode for the intended application. For example, according to some embodiments, a transparent conducting electrode may include the same non-oxide material for both the first and second non-conductive layers 120, 140.

According to other embodiments, one of the first or second non-conductive layers 120, 140 may be selected from one of the above-listed TCOs, while the other of the first or second non-conductive layers 120, 140 may be selected from one of the above listed non-oxides. For example, the first non-conductive layer 120 may be a TCO, while the second non-conductive layer 140 may be a non-oxide, in some embodiments. In other embodiments, the first non-conductive layer 120 may be a non-oxide, while the second non-conductive layer 140 may be a TCO.

For example, an embodiment of a transparent conducting electrode that includes a TCO for one of the first or second non-conductive layers 120, 140, and a non-oxide material for the other one of the first or second non-conductive layers 120, 140 may include a first non-conductive layer 120 formed from ZnO, a conductive layer 130 formed from Ag, and a second non-conductive layer 140 formed from AlN. Another embodiment of a transparent conducting electrode that includes TCO and non-oxide materials for the first and second non-conductive layers 120, 140 may include a first non-conductive layer 120 formed from CeO, a conductive layer 130 formed from Cu, and a second non-conductive layer 140 formed from BN. Various other combinations of TCO and non-oxide materials and conductive materials for the layers 120, 130, 140 of a transparent conducting electrode alternatively may be used to achieve the desired characteristics of the transparent conducting electrode for the intended application.

FIG. 2 is a flowchart of a method of manufacturing an electronic device with one or more transparent conducting electrodes (e.g., transparent conducting electrode 100, FIG. 1), in accordance with an example embodiment. As mentioned previously, the above-described embodiments of transparent conducting electrodes may be used in any of a variety of devices, including but not limited to solar cells, light emitting diodes, light emitting transistors, infrared sensors, ultraviolet sensors, electrochromic devices, touch screens, and liquid crystal displays. Examples of some of these types of devices will be described in more detail in conjunction with FIGS. 3-6. Those of skill in the art in manufacturing each of those types of devices know how to fabricate the basic structures of those devices. Accordingly, fabrication of those basic structures is not discussed herein. Instead, the below-described method focuses on the fabrication steps associated with forming one or more transparent conducting electrodes in or on those devices.

The method may begin, in block 202, by partially fabricating the device up to the point when formation of a transparent conducting electrode is next to be performed. Described generally, block 202 may include forming or providing a substrate (e.g., substrate 110, FIG. 1) associated with the device. The substrate may include polycrystalline, amorphous, or compound structures. In some cases, at this fabrication stage, the substrate may be a simple substrate, such as a sheet of glass or plastic. In other cases, at this fabrication stage, the substrate may be a structure formed from multiple materials and/or layers, and which has undergone a significant number of former fabrication steps. For example, the substrate may be a semiconductor substrate with multiple doped regions and/or layers, including a bulk semiconductor substrate (e.g., silicon, gallium nitride, gallium arsenide, semiconductor on insulator, semiconductor on sapphire, and so on), epitaxial layers, dielectric layers, metal layers, and so on. Examples of various substrates will be discussed in more detail in conjunction with FIGS. 3-6.

In blocks 204-210, one or more transparent conducting electrodes are formed on one or more surfaces of the substrate. More specifically, in block 204, a first layer of a first non-conductive material (e.g., non-conductive layer 120, FIG. 1) is formed on or over a surface of the substrate. As discussed previously, in various embodiments, the first non-conductive layer may be formed from any of a variety of oxides, non-oxides, or other materials. Further, the first non-conductive layer may be formed to have a thickness in a range of about 20 nm to about 30 nm, although it may be thinner or thicker, as well.

The first non-conductive layer may be formed, for example, using a physical vapor deposition (PVD) process. For example, the first non-conductive material may be deposited onto the surface of the substrate using a low temperature (e.g., room temperature) radio frequency (RF) sputtering technique. In alternate embodiments, the first non-conductive layer may be formed using other sputtering techniques (e.g., direct current (DC) sputtering, ion-beam sputtering, ion-assisted sputtering, reactive sputtering, gas flow sputtering, high target utilization sputtering, or high power impulse magnetron sputtering). In still other embodiments, other deposition techniques may be used to deposit the first non-conductive layer, including electron beam PVD, chemical vapor deposition, molecular beam deposition, spray pyrolysis, pulse laser deposition, or other suitable methods.

In block 206, a layer of conductive material (e.g., conductive layer 130, FIG. 1) is formed on the surface of the first non-conductive layer. As discussed previously, in various embodiments, the conductive layer may be formed from any of a variety of conductive materials (e.g., Ag, Cu, Au, Al, graphene, a conducting polymer material, a conducting organic material, and other suitable conductive materials). Further, the conductive layer may be formed to have a thickness in a range of about 8 nm to about 10 nm, although it may be thinner or thicker, as well.

For example, the conductive layer may be deposited onto the surface of the first non-conductive layer using a PVD process, such as DC sputtering. In alternate embodiments, the conductive layer may be formed using other sputtering techniques, electron beam PVD, chemical vapor deposition, molecular beam deposition, spray pyrolysis, pulse laser deposition, or other suitable methods.

In block 208, a second layer of a second non-conductive material (e.g., non-conductive layer 140, FIG. 1) is formed on the surface of the conductive layer. As discussed previously, the second non-conductive layer is formed from a different material than the first non-conductive layer. In various embodiments, the second non-conductive layer may be formed from any of a variety of oxides, non-oxides, or other materials. Further, the second non-conductive layer may be formed to have a thickness in a range of about 20 nm to about 30 nm, although it may be thinner or thicker, as well.

For example, the second non-conductive layer may be deposited onto the surface of the conductive layer using a PVD process, such as RF sputtering. In alternate embodiments, the second non-conductive layer may be formed using other sputtering techniques, electron beam PVD, chemical vapor deposition, molecular beam deposition, spray pyrolysis, pulse laser deposition, or other suitable methods.

In block 210, the stack of material layers for the transparent conducting electrode (i.e., the first non-conductive layer, the conductive layer, and the second non-conductive layer) may be patterned to define a desired shape for each of the one or more transparent conducting electrodes. For example, a resist material may be applied over the second non-conductive layer, the resist material may be patterned to form openings to the surface of the second non-conductive layer, and exposed portions of the electrode material stack may be etched away to the surface of the substrate. The patterned resist may then be removed, thus completing formation of the transparent conducting electrode(s). In other embodiments, other methods may be used to define the transparent conducting electrodes. In still other embodiments, such as embodiments in which the transparent conducting electrode covers the entire substrate surface in the completed device, block 210 may be eliminated.

In block 212, fabrication of the device is completed according to the type of device. This may include, for example, forming other non-electrical and electrical components (including other transparent conducting electrodes), forming electrical connections to the transparent conducting electrode and other devices or conductive features of the device, packaging the device, incorporating the device into a larger electrical system, and so on.

Various types of electrical devices within which embodiments of transparent conducting electrodes may be included will now be described. It should be understood that the below-described and illustrated embodiments are provided for example purposes, and not by way of limitation. Those of skill in the art would understand, based on the description herein, than embodiments of transparent conducting electrodes can be used in a wide variety of devices having different structures from those illustrated and described herein. Accordingly, the use of embodiments of transparent conducting electrodes such as those described herein is intended to be included within the scope of the inventive subject matter.

FIG. 3 is a cross-sectional, side view of a solar cell 300, in accordance with an example embodiment. Essentially, solar cell 300 includes a semiconductor substrate 310, transparent conducting electrode 330 overlying a first surface of the semiconductor substrate 310, contacts 340 coupled to the first surface of the semiconductor substrate 310, and a conductive layer 360 overlying a second surface of the semiconductor substrate 310.

Semiconductor substrate 310 includes a first semiconductor region 312 of a first conductivity type (e.g., p-type), and a second semiconductor region 314 of an opposite conductivity type (e.g., n-type), where the interface between regions 312, 314 forms a p-n junction. For example, the semiconductor substrate 310 may include crystalline silicon (or another semiconductor material) of the first conductivity type, and the second semiconductor region 314 may be formed by introducing dopants of the second conductivity type into the semiconductor substrate 310. Alternatively, the second semiconductor region 314 may be formed over the surface of the first semiconductor region 312, such as by epitaxial growth of the second semiconductor region 314.

In the illustrated embodiment, the first and second semiconductor regions 312, 314 are in direct contact with each other, forming a p-n junction that is proximate to the top surface of the semiconductor substrate 310. In other embodiments, a passivation layer (e.g., an intrinsic a-Si:H passivation layer) may be included between the first and second semiconductor regions 312, 314.

According to an embodiment, a transparent conducting electrode 330 overlies the second semiconductor region 314. The transparent conducting electrode 330 functions as an ARC, which is intended to increase the absorption of energy from incident light 380 by the solar cell 300. Transparent conducting electrode 330 includes a first non-conductive layer 332, a conductive layer 334, and a second non-conductive layer 336. The transparent conducting electrode 330 and its constituent layers 332, 334, 336 may be formed from materials and configured according to the various embodiments discussed previously.

Contacts 340 are formed from a first patterned conductive layer (e.g., formed from aluminum or another conductive material), which is coupled to the top surface of the semiconductor substrate 310 (i.e., to the second semiconductor region 314). The patterned conductive layer may be configured as a grid, for example, which includes openings that allow incident light 380 to enter and pass through the first transparent conducting electrode 330, and to be absorbed by the semiconductor substrate 310. In this manner, carrier generation can occur at the p-n junction that underlies the first transparent conducting electrode 330. The contacts 340 collect the carriers so that they may be delivered to an external load 370.

Similarly, at the other surface of the solar cell 300, a conductive layer 360 (e.g., formed from aluminum or another conductive material) is coupled to the bottom surface of the semiconductor substrate 310 (i.e., to the first semiconductor region 312). The conductive layer 360 allows carriers to be re-injected into the semiconductor substrate 310 from the external load 370.

Although a particular configuration and type of a solar cell is illustrated in FIG. 3 and described above, transparent conducting electrodes according to various embodiments could be used in a variety of other types of solar cells, as well. More specifically, an embodiment of a transparent conducting electrode can be used in place of other electrodes and anti-reflective coatings in a variety of different configurations and types of solar cells. For example, but not by way of limitation, embodiments of transparent conducting electrodes may be used in various types of polysilicon and monocrystalline silicon solar cells, thin film solar cells (e.g., cadmium telluride (CdTe) solar cells, copper indium gallium selenide (CIGS) solar cells, silicon thin film solar cells, gallium arsenide (GaAs) thin film solar cells, and other thin film solar cells), GaAs germanium (Ge) solar cells, multi-junction solar cells (e.g., including GaAs, Ge, and indium gallium phosphide (GaInP) p-n junctions), GaAs nano-pillar array solar cells, optical-thermal solar cells, dye-sensitized solar cells, organic solar cells (e.g., single layer, bi-layer, bulk hererojunction, and tandem device solar cells), polymer solar cells (direct and inverted), nano-structured solar cells (e.g., with nano-particles, C 60, nano-pillars, nano-wires, and nano-films), photoelectrochemical cells, solid state solar cells, solar cells with columnar e-h transport geometries, and other types of solar cells.

In addition to use in solar cells, embodiments of transparent conducting electrodes also can be used in other types of devices that absorb energy and convert the absorbed energy into electrical current. For example, embodiments of transparent conducting electrodes can be used in infrared (IR) sensor devices, IR diodes, and ultraviolet (UV) sensor devices, to name a few.

FIG. 4 is a cross-sectional, side view of a light emitting diode (LED) 400 with a transparent conducting electrode 430, in accordance with an example embodiment. More specifically, LED 400 is a blue/green indium gallium nitride (InGaN)/GaN-based LED, which includes a substrate 410, a transparent conducting electrode 430, and contacts 440, 450. Substrate 410 includes a sapphire base layer 412, an undoped GaN layer 414, a first doped GaN layer 416 (e.g., n-type), a multiple quantum well (MQW) region 418, and a second doped GaN layer 420 (e.g., p-type). The MQW region 418 includes one or more indium gallium nitride (InGaN) quantum wells sandwiched between GaN layers. In an alternate embodiment, the MQW region 418 may include one or more aluminum gallium nitride (AlGaN) quantum wells sandwiched between GaN layers to produce an ultraviolet LED.

According to an embodiment, a transparent conducting electrode 430 overlies the second doped GaN layer 420. The transparent conducting electrode 430 includes a first non-conductive layer 432, a conductive layer 434, and a second non-conductive layer 436. The transparent conducting electrode 430 and its constituent layers 432, 434, 436 may be formed from materials and configured according to the various embodiments discussed previously.

A first (anode) contact 440 contacts the second doped GaN layer 420, and a second (cathode) contact 450 contacts the first doped GaN layer 416. The contacts 440, 450 may be formed from a suitable metal conductor. When an external voltage source 460 applies a sufficient voltage across the first and second contacts 440, 450, charge carriers flow into the MQW region 418 and combine, releasing energy in the form of photons. The photons are emitted from the LED 400 through the transparent conducting electrode 430 in the form of light 470 having a color that depends on the fraction of InGaN to GaN in the MQW region 418.

Although a particular configuration and type of LED is illustrated in FIG. 4 and described above, transparent conducting electrodes according to various embodiments could be used in a variety of other types of LEDs, as well. More specifically, an embodiment of a transparent conducting electrode can be used in place of other electrodes in a variety of different configurations and types of LEDs. For example, but not by way of limitation, embodiments of transparent conducting electrodes may be used in gallium arsenide (GaAs) LEDs, silicon carbide (SiC) LEDs, silicon LEDs, aluminum gallium arsenide (AlGaAs) LEDs, gallium arsenide phosphide (GaAsP) LEDs, aluminum gallium indium phosphide (AlGaInP) LEDs, gallium(III) phosphide (GaP) LEDs, zinc selenide (ZnSe), InGaN LEDs, diamond LEDs, boron nitride (BN) LEDs, aluminum nitride (AlN) LEDs, aluminum gallium nitride (AlGaN) LEDs, aluminum gallium indium nitride (AlGaInN) LEDs, phosphor-based LEDs, organic LEDs (OLEDs), LEDs formed on yttria-stabilized-zirconia (YSZ) substrates (e.g., including n-type and p-type junctions formed from InGaO₃/a-HfOx or ZnO/SrCu₂O₂), LEDs formed on glass substrates (e.g., including poly(3-hexylthiophene)/phenyl-C61-butyric acid methyl ester (P3HT:PCBM), ZnO, and/or graphene), and other types of LEDs.

Further, embodiments of transparent conducting electrodes may be used in other types of light emitting devices, such as light emitting transistors (LETs), for example, where the transparent conducting electrode may function as a gate electrode and/or overlie a p-n junction in the LET.

In addition, embodiments of transparent conducting electrodes may be applied as over surfaces of a transparent substrate or structure to enable an electromagnetic field to be applied across the substrate or structure. For example, embodiments of transparent conducting electrodes may be particularly useful in electrochromic devices and liquid crystal display devices.

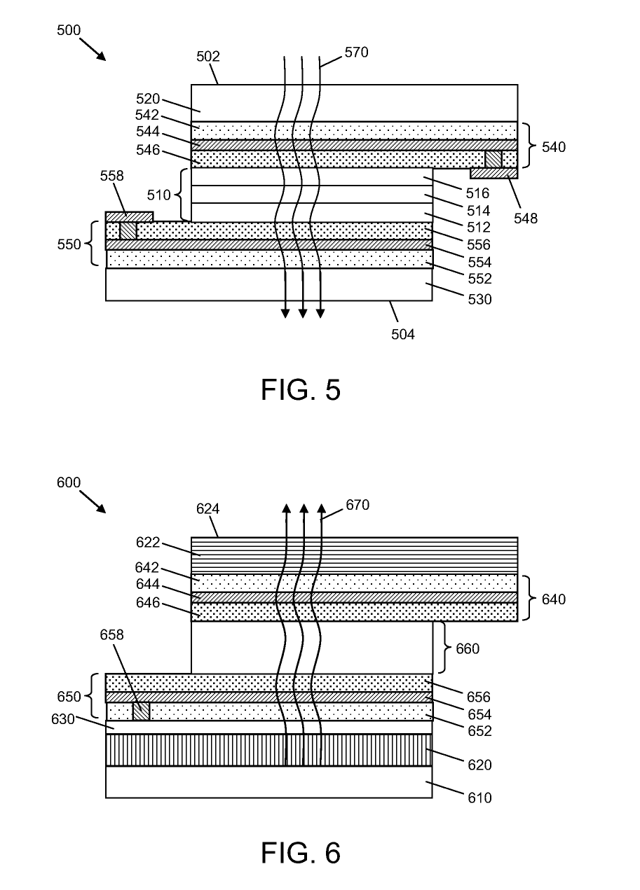

FIG. 5 is a cross-sectional, side view of a portion of an electrochromic device 500, in accordance with an embodiment, with first and second outer surfaces 502, 504. According to an embodiment, electrochromic device 500 may be transparent between first and second surfaces 502, 504, although with variable opacity, as will be described below. In such an embodiment, electrochromic device 500 includes a core 510, first and second transparent substrates 520, 530, and first and second transparent conducting electrodes 540, 550. For example, the first and second transparent substrates 520, 530 may include glass, plastic, or another suitable transparent material. In an alternate embodiment, electrochromic device 500 may be configured to receive and reflect light, rather than being transparent. In such an embodiment, substrate 530 instead may be opaque, and second conducting electrode 550 may be a reflective electrode.

Each of the first and second conducting electrodes 540, 550 includes a first non-conductive layer 542, 552, a conductive layer 544, 554, and a second non-conductive layer 546, 556. The transparent conducting electrodes 540, 550 and their constituent layers 542, 544, 546, 552, 554, 556 may be formed from materials and configured according to the various embodiments discussed previously. Further, device 500 includes conductive contacts 548, 558 that provide for electrical contact with conductive layers 544, 554. In the illustrated embodiment, the conductive contacts 548, 558 include conductive pads and vias that directly contact conductive layers 544, 554. In an alternate embodiment, at least a portion of non-conductive layer 556 may be doped to have an intermediate resistance, so that current may flow from an overlying conductive pad (or other structure) through the non-conductive layer 556 to the conductive layer 554. A voltage applied across contacts 548, 558 results in the generation of an electromagnetic field between conductive layers 544, 554 (or an electromagnetic field through core 510).

Core 510 includes an electrochromic layer 512 (e.g., an electrochromic polymer, a transition metal hydride, or another suitable material), an ion conductor or electrolyte layer 514 (e.g., a gel electrolyte or another suitable material), and an ion storage layer 516. When a sufficient voltage is applied across the conductive layers 544, 554, resulting in a sufficiently strong electromagnetic field across the core 510, the opacity of the electrochromic layer 512 changes. Accordingly, the transmission properties of light 570 through the core 510 (and thus through device 500 between the first and second surfaces 502, 504) may be altered.

FIG. 6 is a cross-sectional, side view of a backlit, active matrix liquid crystal display (LCD) device 600, in accordance with an example embodiment. More specifically, FIG. 6 depicts a cross-sectional, side view of a single pixel of an LCD device 600. An actual LCD device would include an array of such pixels, each of which may be configured substantially as shown in FIG. 6, and each of which may be separately controlled. For the purpose of clarity and ease of description, however, the construction and operation of a single pixel is illustrated and described.

According to an embodiment, LCD device 600 includes a backlight 610, first and second transparent polarized substrates 620, 622 (with perpendicular polarizations), a thin film transistor (TFT) layer 630, first and second transparent conducting electrodes 640, 650, and liquid crystal layer 660. A color filter (not illustrated) may be coupled to the second transparent substrate 622 to define the color of the pixel. Backlight 610 may include, for example, a fluorescent lamp or other light source, which may be on continuously when the display is active.

Each of the first and second conducting electrodes 640, 650 includes a first non-conductive layer 642, 652, a conductive layer 644, 654, and a second non-conductive layer 646, 656. The transparent conducting electrodes 640, 650 and their constituent layers 642, 644, 646, 652, 654, 656 may be formed from materials and configured according to the various embodiments discussed previously.

According to an embodiment, the first conducting electrode 640 may be common to all pixels of the LCD device 600, and the conductive layer 644 of the first conducting electrode 640 may be coupled to a common voltage reference (e.g., ground or some other reference). In contrast, the second conducting electrode 650 may be associated with a single pixel, and a TFT of the TFT layer 630 may be coupled to the conductive layer 652 (e.g., through conductive via 658), and used to control a voltage applied to the conductive layer 652 of the second conducting electrode 650. In this manner, the voltage difference between conductive layers 644, 654 may be controlled. During operation, a voltage difference applied between conductive layers 644, 654 results in the generation of an electromagnetic field through liquid crystal layer 660.

Liquid crystal layer 660 includes an electrically-controlled, light-polarizing liquid contained in a cell between the first and second conducting electrodes 640, 650. When little or no voltage is applied across the conductive layers 644, 654, the liquid crystal molecules are misaligned in such a manner that the liquid crystal layer 660 does not allow significant amounts of light from backlight 610 to pass through the liquid crystal layer 660. However, when a sufficient voltage is applied across the conductive layers 644, 654, resulting in a sufficiently strong electromagnetic field across the liquid crystal layer 660, the liquid crystal molecules align in a manner that allows the light 670 produced by backlight 610 to pass through liquid crystal layer 660 and the outer surface 624 of substrate 622 (and its associated color filter) toward an observer.

Although a particular embodiment of an LCD display device is illustrated and described above, embodiments of transparent conducting electrodes may be used in various types of backlit, reflective, active, and passive LCD displays. Further, in addition to LCD devices, embodiments of transparent conducting electrodes also may be used in other types of displays. For example, embodiments of transparent conducting electrodes may be used in resistive touch screens and/or capacitive touch screens. Further, embodiments of transparent conducting electrodes may be applied to other types of transparent surfaces to provide other functionalities. For example, transparent conducting electrodes may be applied to front and back surfaces of windshields and windows, and voltages between the transparent conducting electrodes may generate sufficient heat to defrost the windshields and windows. A wide variety of other potential applications exist for the various embodiments of transparent conducting electrodes described herein.

Various embodiments of electronic devices and methods of their manufacture have been described above. An embodiment of an electronic device includes a substrate having a substrate top surface, and a transparent conducting electrode coupled to the substrate top surface. The transparent conducting electrode includes a first non-conductive layer formed from a first non-conductive material, a conductive layer on the first non-conductive layer and formed from an electrically conductive material, and a second non-conductive layer on the conductive layer and formed from a second non-conductive material that is different from the first non-conductive material.

An embodiment of a method of manufacturing an electronic device that includes a transparent conducting electrode includes forming a first non-conductive layer of the transparent conducting electrode over a top surface of a substrate, where the first non-conductive layer includes a first non-conductive material. The method further includes forming a conductive layer of the transparent conducting electrode on the first non-conductive layer, where the conductive layer includes an electrically conductive material. The method further includes forming a second non-conductive layer of the transparent conducting electrode on the conductive layer. The second non-conductive layer includes a second non-conductive material that is different from the first non-conductive material.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

The foregoing detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or the foregoing detailed description.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. An electronic device comprising:
a substrate having a substrate top surface; and
a transparent conducting electrode coupled to the substrate top surface, wherein the transparent conducting electrode includes a first non-conductive layer formed from a first non-conductive material, a conductive layer on the first non-conductive layer and formed from an electrically conductive material, and a second non-conductive layer on the conductive layer and formed from a second non-conductive material that is different from the first non-conductive material.

2. The device of claim 1, wherein the first and second non-conductive materials are selected from aluminum oxide (Al₂O₃), barium oxide/tellurium oxide (BaO—TeO₂), indium tin oxide (InSnO), cerium oxide (CeO), nickel oxide (NiO), niobium oxide (NbO), silicon dioxide (SiO₂), tin oxide (SnO), tantalum oxide (Ta₂O₅), tungsten oxide (WO), zinc oxide (ZnO), chromium oxide (CrO), manganese oxide (MnO₂), titanium oxide (TiO₂), zirconium oxide (ZrO), boron bismuth oxide (BBiO), indium tin oxide (ITO), fluorine doped tin oxide (FTO), aluminum doped zinc oxide (AZO), indium-doped cadmium-oxide, and a doped metal oxide.

3. The device of claim 1, wherein the first and second non-conductive materials are selected from a nitride, a metal-nitride, a semiconductor-nitride, an oxynitride, a metal-oxynitride, a semiconductor-oxynitride, a boride, a hydride, a fluoride, a carbide, a nanocarbon, a selenide, a sulfide, a silicate, an aluminate, diamond, diamondoid, a polymer, and an organic non-oxide.

4. The device of claim 3, wherein the first and second non-conductive materials are selected from aluminum nitride (AlN), boron nitride (BN), carbon nitride (CN), iron boron nitride (FeBN), tin nitride (SnN), silicon nitride (Si₃N₄), titanium nitride (TiN), titanium aluminum nitride (TiAlN), chromium nitride (CrN), zinc nitride (ZnN), and copper nitride (CuN).

5. The device of claim 1, wherein:
one of the first or second non-conductive materials is selected from aluminum oxide (Al₂O₃), barium oxide/tellurium oxide (BaO—TeO₂), indium tin oxide (InSnO), cerium oxide (CeO), nickel oxide (NiO), niobium oxide (NbO), silicon dioxide (SiO₂), tin oxide (SnO), tantalum oxide (Ta₂O₅), tungsten oxide (WO), zinc oxide (ZnO), chromium oxide (CrO), manganese oxide (MnO₂), titanium oxide (TiO₂), zirconium oxide (ZrO), boron bismuth oxide (BBiO), indium tin oxide (ITO), fluorine doped tin oxide (FTO), aluminum doped zinc oxide (AZO), indium-doped cadmium-oxide, and a doped metal oxide, and
the other one of the first or second non-conductive materials is selected from a nitride, a metal-nitride, a semiconductor-nitride, an oxynitride, a metal-oxynitride, a semiconductor-oxynitride, a boride, a hydride, a fluoride, a carbide, a nanocarbon, a selenide, a sulfide, a silicate, an aluminate, diamond, diamondoid, a polymer, and an organic non-oxide.

6. The device of claim 1, wherein the electrically conductive material of the conductive layer is selected from silver (Ag), copper (Cu), gold (Au), aluminum (Al), graphene, a conducting polymer material, a conducting organic material, and a carbon nanotube sheet.

7. The device of claim 1, wherein:
the first non-conductive layer has a thickness in a range of 20 nanometers to 30 nanometers;
the conductive layer has a thickness in a range of 8 nanometers to 10 nanometers; and
the second non-conductive layer has a thickness in a range of 20 nanometers to 30 nanometers.

8. The device of claim 1, wherein the substrate is selected from glass, a semiconductor material, and a plastic.

9. The device of claim 1, wherein the optical transmittance of the first and second non-conductive layers is greater than 70 percent.

10. The device of claim 1, wherein the device is a solar cell, the substrate includes a p-n junction between a first semiconductor region of a first conductivity type and a second semiconductor region of a second conductivity type, and the transparent conducting electrode overlies the p-n junction so that electromagnetic radiation may pass through the transparent conducting electrode into the substrate to generate charge carriers in the p-n junction.

11. The device of claim 10, wherein the solar cell is selected from a silicon solar cell, a thin film solar cell, a gallium arsenide (GaAs) germanium (Ge) solar cell, a multi-junction solar cell, a GaAs nano-pillar array solar cell, an optical-thermal solar cell, a dye-sensitized solar cell, an organic solar cell, a polymer solar cell, a nano-structured solar cell, a photoelectrochemical cell, a solid state solar cell, and a solar cell with columnar e-h transport geometries.

12. The device of claim 1, wherein the device is selected from an infrared (IR) sensor device, an IR diode, and an ultraviolet (UV) sensor device.

13. The device of claim 1, wherein the device is a light emitting diode, the substrate includes a first semiconductor region of a first conductivity type and a second semiconductor region of a second conductivity type, and the transparent conducting electrode overlies the substrate so that photons generated in the substrate may be emitted from the device through the transparent conducting electrode.

14. The device of claim 1, wherein the device is a light emitting transistor.

15. The device of claim 1, wherein the device is an electrochromic device, the substrate is a transparent substrate, and the device further comprises:
a second substrate;
a second transparent conducting electrode coupled to a top surface of the second substrate; and
a core positioned between the transparent conducting electrode and the second transparent conducting electrode, wherein the core includes an electrochromic layer, an ion conductor layer, and an ion storage layer, and when a voltage is applied across the first and second transparent conducting electrodes an electromagnetic field is generated through the core to change an opacity of the core.

16. The device of claim 1, wherein the device is a liquid crystal device, and the device further comprises:
a backlight;
a first transparent polarized substrate coupled to the backlight;
a first transparent conducting electrode coupled to the first transparent polarized substrate;
a liquid crystal layer coupled to the first transparent conducting electrode and including a plurality of liquid crystal molecules;
a second transparent conducting electrode coupled to the liquid crystal layer; and
a second transparent polarized substrate coupled to the second transparent conducting electrode, wherein a voltage applied across the first and second transparent conducting electrodes affects an alignment of the liquid crystal molecules to affect how much light generated by the backlight passes through the liquid crystal layer.

17. A method of manufacturing an electronic device that includes a transparent conducting electrode, the method comprising the steps of:
forming a first non-conductive layer of the transparent conducting electrode over a top surface of a substrate, wherein the first non-conductive layer comprises a first non-conductive material;
forming a conductive layer of the transparent conducting electrode on the first non-conductive layer, wherein the conductive layer comprises an electrically conductive material; and
forming a second non-conductive layer of the transparent conducting electrode on the conductive layer, wherein the second non-conductive layer comprises a second non-conductive material that is different from the first non-conductive material.

18. The method of claim 17, wherein forming the first non-conductive layer, the conductive layer, and the second non-conductive layer each comprises performing a sputtering process.

19. The method of claim 17, wherein the first and second non-conductive materials are selected from aluminum oxide (Al₂O₃), barium oxide/tellurium oxide (BaO—TeO₂), indium tin oxide (InSnO), cerium oxide (CeO), nickel oxide (NiO), niobium oxide (NbO), silicon dioxide (SiO₂), tin oxide (SnO), tantalum oxide (Ta₂O₅), tungsten oxide (WO), zinc oxide (ZnO), chromium oxide (CrO), manganese oxide (MnO₂), titanium oxide (TiO₂), zirconium oxide (ZrO), boron bismuth oxide (BBiO), indium tin oxide (ITO), fluorine doped tin oxide (FTO), aluminum doped zinc oxide (AZO), indium-doped cadmium-oxide, and a doped metal oxide.

20. The method of claim 17, wherein the first and second non-conductive materials are selected from a nitride, a metal-nitride, a semiconductor-nitride, an oxynitride, a metal-oxynitride, a semiconductor-oxynitride, a boride, a hydride, a fluoride, a carbide, a nanocarbon, a selenide, a sulfide, a silicate, an aluminate, diamond, diamondoid, a polymer, and an organic non-oxide.

21. The method of claim 17, wherein:
one of the first or second non-conductive materials is selected from aluminum oxide (Al₂O₃), barium oxide/tellurium oxide (BaO—TeO₂), indium tin oxide (InSnO), cerium oxide (CeO), nickel oxide (NiO), niobium oxide (NbO), silicon dioxide (SiO₂), tin oxide (SnO), tantalum oxide (Ta₂O₅), tungsten oxide (WO), zinc oxide (ZnO), chromium oxide (CrO), manganese oxide (MnO₂), titanium oxide (TiO₂), zirconium oxide (ZrO), boron bismuth oxide (BBiO), indium tin oxide (ITO), fluorine doped tin oxide (FTO), aluminum doped zinc oxide (AZO), indium-doped cadmium-oxide, and a doped metal oxide, and
the other one of the first or second non-conductive materials is selected from a nitride, a metal-nitride, a semiconductor-nitride, an oxynitride, a metal-oxynitride, a semiconductor-oxynitride, a boride, a hydride, a fluoride, a carbide, a nanocarbon, a selenide, a sulfide, a silicate, an aluminate, diamond, diamondoid, a polymer, and an organic non-oxide.
